(19) United States
(12) Patent Application Publication
(10) Pub. No.: US 2025/0056829 A1
(43) Pub. Date: Feb. 13, 2025

(54) HIGH-FREQUENCY DRAIN-EXTENDED METAL-OXIDE-SEMICONDUCTOR (DEMOS) DEVICES AND METHODS FOR PRODUCING THE SAME

(71) Applicants: ZHEJIANG UNIVERSITY, Hangzhou (CN); BEIJING SMARTCHIP MICROELECTRONICS TECHNOLOGY CO., LTD., Beijing (CN)

(72) Inventors: Kai XU, Hangzhou (CN); Bo WU, Beijing (CN); Xiaoyun HUANG, Hangzhou (CN); Yanning CHEN, Beijing (CN); Fang LIU, Beijing (CN); Dawei GAO, Hangzhou (CN); Yongyu WU, Hangzhou (CN)

(73) Assignees: ZHEJIANG UNIVERSITY, Hangzhou (CN); BEIJING SMARTCHIP MICROELECTRONICS TECHNOLOGY CO., LTD., Beijing (CN)

(21) Appl. No.: 18/926,281

(22) Filed: Oct. 24, 2024

(30) Foreign Application Priority Data
Nov. 21, 2023 (CN) 202311556395.9

(51) Int. Cl. H01L 29/78; H01L 21/225; H01L 21/265; H01L 21/66; H01L 29/66

(52) U.S. Cl. CPC H01L 29/7835; H01L 21/2253; H01L 21/26513; H01L 22/20; H01L 29/66492; H01L 29/66681; H01L 29/7816

(57) ABSTRACT

Provided are a DEMOS device and a method for producing the same. The DEMOS device includes a silicon substrate, a well region, a source region, a drain region, a drift region, a lightly doped region, a gate structure, and a field plate structure. The gate structure includes a primary gate structure and a secondary gate structure. The primary gate structure is disposed on a p-type well or an n-type well of the well region, and configured to receive an input signal. The secondary gate structure covers part of the p-type well and part of the drift region, or part of the n-type well and part of the drift region. The secondary gate structure is configured to receive a fixed bias voltage. The short gate length of the primary gate structure significantly reduces gate-drain capacitance, and increases cutoff frequency, enhancing high-frequency performance, while having minimal impact on breakdown voltage.

### CROSS-REFERENCE TO RELATED APPLICATIONS

This application claims priority to Chinese Patent Application No. 202311556395.9, filed on Nov. 21, 2023, the entire contents of which are incorporated herein by reference.

### TECHNICAL FIELD

The present disclosure relates to the field of semiconductor integrated circuits, and in particular to high-frequency DEMOS devices and methods for producing the same.

### BACKGROUND

Drain-extended metal-oxide-semiconductor (DEMOS) is a high-voltage MOS device characterized by a high breakdown voltage and low on-resistance, commonly used in high-voltage power modules within a BCD process

As shown in FIG. 1, using an n-type device as an example, conventional DEMOS devices generally include a silicon substrate, a well region, a drift region, a gate structure, a substrate electrode lead-out region, an isolation ring lead-out region, a body electrode lead-out region, a source region, and a drain region.

The silicon substrate includes a p-type epitaxial substrate 101 and an n-type buried layer 102. Shallow trench isolation oxides are formed on a surface of the silicon substrate. The shallow trench isolation oxides include a first isolation oxide 107a, a second isolation oxide 107b, a third isolation oxide 107c, a fourth isolation oxide 107d, and a fifth isolation oxide 107e. The shallow trench isolation oxides isolate an active region of the DEMOS device.

The well region includes a deep n-type well 103 on the n-type buried layer 102, an n-type well 104 on the deep n-type well 103, a p-type well 105a on the p-type epitaxial substrate 101 and outside a region surrounded by the n-type buried layer 102, and a p-type well 105b above the p-type epitaxial substrate 101 and inside the region surrounded by the n-type buried layer 102.

The drift region includes an n-type drift region 106.

The gate structure includes a gate oxide layer 110, a gate polysilicon layer 111, and a silicon nitride sidewall 112. The gate structure covers part of the p-type well 105b and part of the n-type drift region 106.

The substrate electrode lead-out region includes a p-type heavily doped region 108a on a surface of the p-type well 105a.

The isolation ring lead-out region includes an n-type heavily doped region 109a on a surface of the n-type well 104.

The body electrode lead-out region includes a p-type heavily doped region 108b on a surface of the p-type well 105b.

The source region includes an n-type heavily doped region 109b on the surface of the p-type well 105b. The source region is aligned with a first side of the gate structure.

The drain region includes an n-type heavily doped region 109c on a surface of the n-type drift region 106. The drain region is spaced apart from a second side of the gate structure.

With the development of high-frequency communication technologies such as 5G, devices used as radio frequency power amplifiers require higher operating frequencies and greater breakdown voltages. However, the gate structure of conventional DEMOS devices has a relatively long gate length, leading to a relatively high gate capacitance, which severely limits a maximum cutoff frequency (fₜ) of the DEMOS device and thus restricts the high-frequency performance of the DEMOS device. On the other hand, the uneven internal electric field distribution in conventional DEMOS devices significantly limits the breakdown voltage (V_{BD}) of the device.

### SUMMARY

To address the issues of low maximum cutoff frequency and low breakdown voltage in high-frequency DEMOS devices, the present disclosure provides a high-frequency DEMOS device and a method for producing the same.

One or more embodiments of the present disclosure provide a DEMOS device comprising a silicon substrate, a well region, a source region, a drain region, a drift region, a lightly doped region, a gate structure, and a field plate structure.

The gate structure includes a primary gate structure and a secondary gate structure. The primary gate structure is disposed on a p-type well or an n-type well of the well region, and the primary gate structure is configured to receive an input signal. The secondary gate structure covers part of the p-type well and part of the drift region, or the secondary gate structure covers part of the n-type well and part of the drift region. The secondary gate structure is configured to receive a fixed bias voltage.

A gate length of the primary gate structure is smaller than a gate length of a gate structure of a conventional DEMOS device.

The lightly doped region is disposed on a surface of the p-type well or a surface of the n-type well, and the lightly doped region is located between the primary gate structure and the secondary gate structure.

The field plate structure covers the lightly doped region.

In some embodiments, the gate length of the primary gate structure satisfies a predetermined gate length condition, the predetermined gate length condition being related to a minimum allowable gate length of the primary gate structure under a current process node.

In some embodiments, a material of the field plate structure is a high dielectric constant material.

In some embodiments, the primary gate structure includes a gate oxide layer, a gate polysilicon layer, and a silicon nitride sidewall.

In some embodiments, the secondary gate structure includes a gate oxide layer, a gate polysilicon layer, and a silicon nitride sidewall.

One or more embodiments of the present disclosure provide a method of producing the high-frequency DEMOS device described above. The method includes:

Providing a p-type epitaxial substrate having an n-type buried layer, and performing localized oxidation isolation on a portion of the p-type epitaxial substrate to define an active region of the high-frequency DEMOS device.

Implanting and diffusing n-type ions and p-type ions separately into a DEMOS region to form the n-type well, the drift region, and the p-type well of the high-frequency DEMOS device.

Growing a gate oxide layer and depositing polycrystalline silicon in the DEMOS region to form the primary gate structure and the secondary gate structure of the high-frequency DEMOS device.

Lightly implanting ions into the region between the primary gate structure and the secondary gate structure to form the lightly doped region of the high-frequency DEMOS device.

Depositing a layer of a high dielectric constant material on the lightly doped region to form the field plate structure of the high-frequency DEMOS device.

Forming a silicon nitride sidewall isolation structure of the primary gate structure and a silicon nitride sidewall isolation structure of the secondary gate structure in the DEMOS region.

Performing self-alignment and separately implanting a predetermined dose of n-type ions and p-type ions in an isolation ring lead-out region, the source region, the drain region, a substrate electrode lead-out region, and a body electrode lead-out region of the DEMOS region to form an n-type isolation ring lead-out region, an n-type source region, an n-type drain region, a p-type substrate electrode lead-out region, and a p-type body electrode lead-out region of the high-frequency DEMOS device; or performing self-alignment and separately implanting the predetermined dose of n-type ions and p-type ions in the isolation ring lead-out region, the source region, the drain region, the substrate electrode lead-out region, and the body electrode lead-out region of the DEMOS region to form the n-type isolation ring lead-out region, an n-type body electrode lead-out region, the p-type substrate electrode lead-out region, a p-type source region, and a p-type drain region of the high-frequency DEMOS device. The predetermined dose is not less than a preset value.

### BRIEF DESCRIPTION OF THE DRAWINGS

The present disclosure is further described in terms of exemplary embodiments. These exemplary embodiments are described in detail with reference to the drawings. These embodiments are non-limiting exemplary embodiments, in which like reference numerals represent similar structures throughout the several views of the drawings, and wherein:

FIG. 1 is a schematic diagram of an exemplary structure of a conventional DEMOS device;

FIG. 2 is a schematic diagram of an exemplary structure of a high-frequency DEMOS device according to some embodiments of the present disclosure;

FIG. 3 is a flowchart of an exemplary process of a method for producing a high-frequency DEMOS device according to some embodiments of the present disclosure;

FIG. 4 is a flowchart of another exemplary process of a method for producing a high-frequency DEMOS device according to some embodiments of the present disclosure;

FIG. 5 is a flowchart of an exemplary process for adjusting at least one of an initial implantation dose of an ion implantation device and an initial deposition time of a thin film deposition device according to some embodiments of the present disclosure; and

FIG. 6 is a flowchart of an exemplary process for determining a predicted breakdown voltage range of a high-frequency DEMOS device according to some embodiments of the present disclosure.

### DETAILED DESCRIPTION

In order to provide a clearer understanding of the technical solutions of the embodiments described in the present disclosure, a brief introduction to the drawings required in the description of the embodiments is given below. It is evident that the drawings described below are merely some examples or embodiments of the present disclosure, and for those skilled in the art, the present disclosure may be applied to other similar situations without exercising creative labor. Unless otherwise indicated or stated in the context, the same reference numerals in the drawings represent the same structures or operations.

It should be understood that the terms “system,” “device,” “unit,” and/or “module” used herein are ways for distinguishing different levels of components, elements, parts, or assemblies. However, if other terms can achieve the same purpose, they may be used as alternatives.

As indicated in the present disclosure and in the claims, the singular forms “a,” “an,” and “the” may be intended to include the plural forms as well, unless the context clearly indicates otherwise. In general, the terms “comprise,” “comprises,” and/or “comprising,” “include,” “includes,” and/or “including,” when used in this disclosure, specify the presence of stated features, integers, steps, operations, elements, and/or components, but do not preclude the presence or addition of one or more other features, integers, steps, operations, elements, components, and/or groups thereof.

Flowcharts are used in the present disclosure to illustrate the operations performed by the system according to the embodiments described herein. It should be understood that the operations may not necessarily be performed in the exact sequence depicted. Instead, the operations may be performed in reverse order or concurrently. Additionally, other operations may be added to these processes, or one or more operations may be removed.

The following description is provided in conjunction with the accompanying drawings and embodiments.

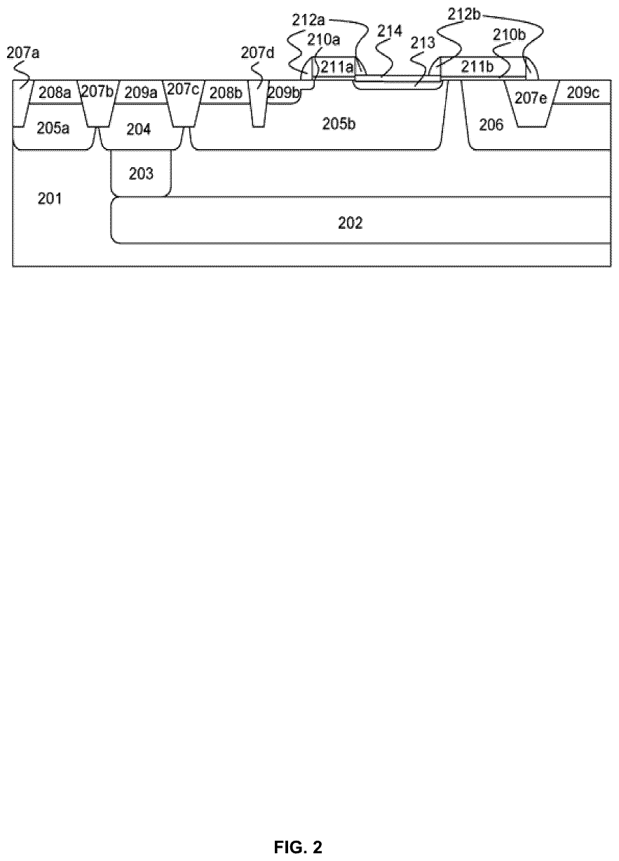

FIG. 2 is a schematic diagram of an exemplary structure of a high-frequency DEMOS device according to some embodiments of the present disclosure. The high-frequency DEMOS device refers to a DEMOS device with an operating frequency range of 300 kHz to 3 GHZ. Hereinafter, the high-frequency DEMOS device is referred to as the DEMOS device.

As shown in FIG. 2, taking an n-type device as an example, the high-frequency DEMOS device at least includes a silicon substrate, a well region, a source region, a drain region, a drift region, a lightly doped region, a gate structure, and a field plate structure.

The silicon substrate refers to a substrate made from silicon, used as a base material in the manufacturing of semiconductor devices.

The silicon substrate includes a p-type epitaxial substrate 201 and an n-type buried layer 202. Shallow trench isolation oxides are formed on a surface of the silicon substrate. The shallow trench isolation oxides include a first isolation oxide 207a, a second isolation oxide 207b, a third isolation oxide 207c, a fourth isolation oxide 207d, and a fifth isolation oxide 207e. The shallow trench isolation oxides isolate an active region of the DEMOS device.

The well region includes a deep n-type well 203 on top of the n-type buried layer 202, an n-type well 204 on top of the deep n-type well 203, a p-type well 205a that is on the p-type epitaxial substrate 201 and outside a region surrounded by the n-type buried layer 202, and a p-type well 205b that is above the p-type epitaxial substrate 201 and inside the region surrounded by the n-type buried layer 202.

The drift region includes an n-type drift region 206.

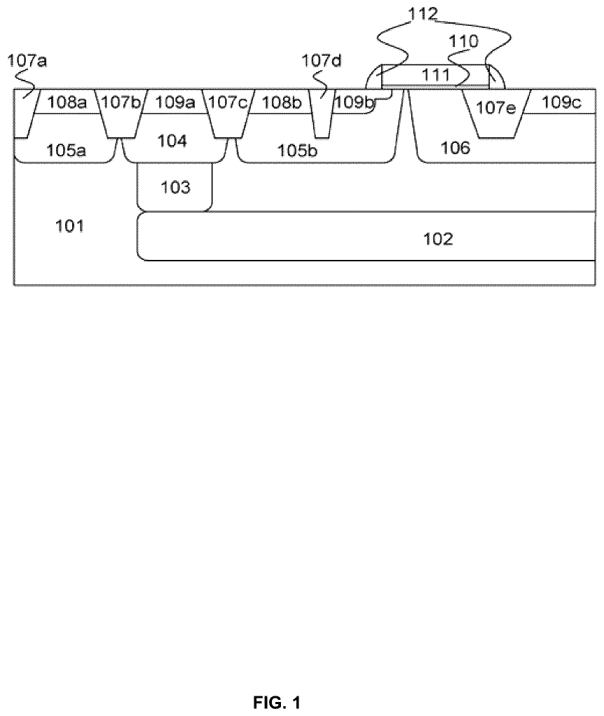

The gate structure includes a relatively short primary gate structure and a relatively long secondary gate structure. Relatively short means that a gate length of the primary gate structure is smaller than a gate length of a gate structure of a conventional DEMOS device. Relatively long means that a gate length of the secondary gate structure is greater than the gate length of the primary gate structure. The structure of the conventional DEMOS device is shown in FIG. 1. The primary gate structure is typically ⅕ of the gate length of the gate structure of the conventional DEMOS device. In some embodiments, the gate length of the primary gate structure may be 1/10 of the gate length of the gate structure of the conventional DEMOS device. The conventional DEMOS devices typically have a gate structure with a gate length of about 2 μm. For example, the gate structure of the conventional DEMOS device may have a gate length of 2 μm. The gate length of the gate structure of the present disclosure may be slightly smaller than the gate length of the gate structure of the conventional DEMOS device.

In some embodiments, the primary gate structure and the secondary gate structure includes different gate oxide layers, gate polysilicon layers, and silicon nitride sidewalls.

In some embodiments, the primary gate structure includes a first gate oxide layer 210a, a first gate polysilicon layer 211a, and a first silicon nitride sidewall 212a, and the secondary gate structure includes a second gate oxide layer 210b, a second gate polysilicon layer 211b, and a second silicon nitride sidewall 212b. The primary gate structure is disposed on the p-type well 205b, and the secondary gate structure covers a portion of the p-type well 205b and a portion of the n-type drift region 206.

The lightly doped region includes a relatively shallow lightly doped implanted region 213. The lightly doped region is located on a surface of the p-type well 205b and between the primary gate structure and the secondary gate structure. The relatively shallow lightly doped implanted region 213 is a lightly doped implanted region 213 with an implantation depth ranging from 20 nm to 50 nm.

The field plate structure includes a high-k material field plate structure 214. The field plate structure covers the lightly doped region. The high-k material refers to a high dielectric constant material. The high dielectric constant material may include hafnium dioxide, zirconium dioxide, titanium dioxide, or the like.

The substrate electrode lead-out region includes a p-type heavily doped region 208a on a surface of the p-type well 205a.

The isolation ring lead-out region includes an n-type heavily doped region 209a on a surface of the n-type well 204.

The body electrode lead-out region includes a p-type heavily doped region 208b on the surface of the p-type well 205b.

The source region includes an n-type heavily doped region 209b on the surface of the p-type well 205b. The source region is self-aligned with a first side of the primary gate structure. The first side of the primary gate structure refers to a side of the first silicon nitride sidewall 212a adjacent to the n-type heavily doped region 209b.

The drain region includes an n-type heavily doped region 209c on a surface of the n-type drift region 206. The drain region is self-aligned with a second side of the secondary gate structure.

The second side of the secondary gate structure refers to a side of the second silicon nitride sidewall 212b that is closest to the n-type heavily doped region 209c.

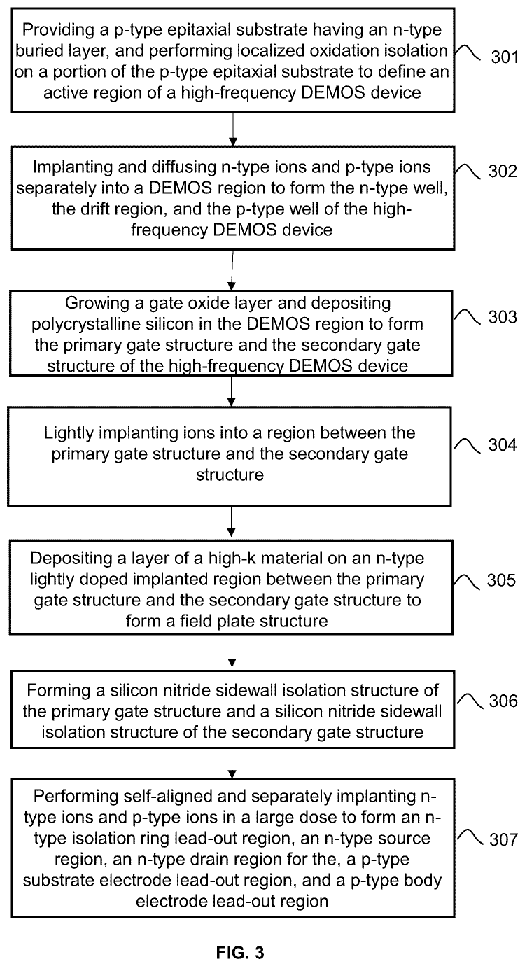

FIG. 3 is a flowchart of an exemplary process of a method for producing a high-frequency DEMOS device according to some embodiments of the present disclosure. The method shown in FIG. 3 may produce the high-frequency DEMOS device shown in FIG. 2, and the method includes operations 301-307 as follows:

In 301, a p-type epitaxial substrate having an n-type buried layer is provided, and localized oxidation isolation may be performed on a portion of a substrate to define an active region of the high-frequency DEMOS device. The portion of the substrate may include regions where a first isolation oxide 207a, a second isolation oxide 207b, a third isolation oxide 207c, a fourth isolation oxide 207d, and a fifth isolation oxide 207e are located.

In 302, n-type ions and p-type ions are separately implanted and diffused in a DEMOS region to form an n-type well, an n-type drift region, and a p-type well of the device high-frequency DEMOS device.

In 303, a gate oxide layer is grown and polycrystalline silicon is deposited to form a primary gate structure and a secondary gate structure.

In 304, n-type ions are implanted lightly into a region between the primary gate structure and the secondary gate structure.

In 305, a layer of a high-k material is deposited on an n-type lightly doped implanted region between the primary gate structure and the secondary gate structure to form a field plate structure.

In 306, a silicon nitride sidewall isolation structure of the primary gate structure and a silicon nitride sidewall isolation structure of the secondary gate structure are formed.

In 307, self-aligned is performed and n-type ions and p-type ions are separately implanted in a large dose to form an n-type isolation ring lead-out region, an n-type source region, an n-type drain region for the, a p-type substrate electrode lead-out region, and a p-type body electrode lead-out region. The amount of the large dose may be preset. The large dose refers to that the injection of the n-type ions and p-type ions are greater than 10¹⁵ cm⁻².

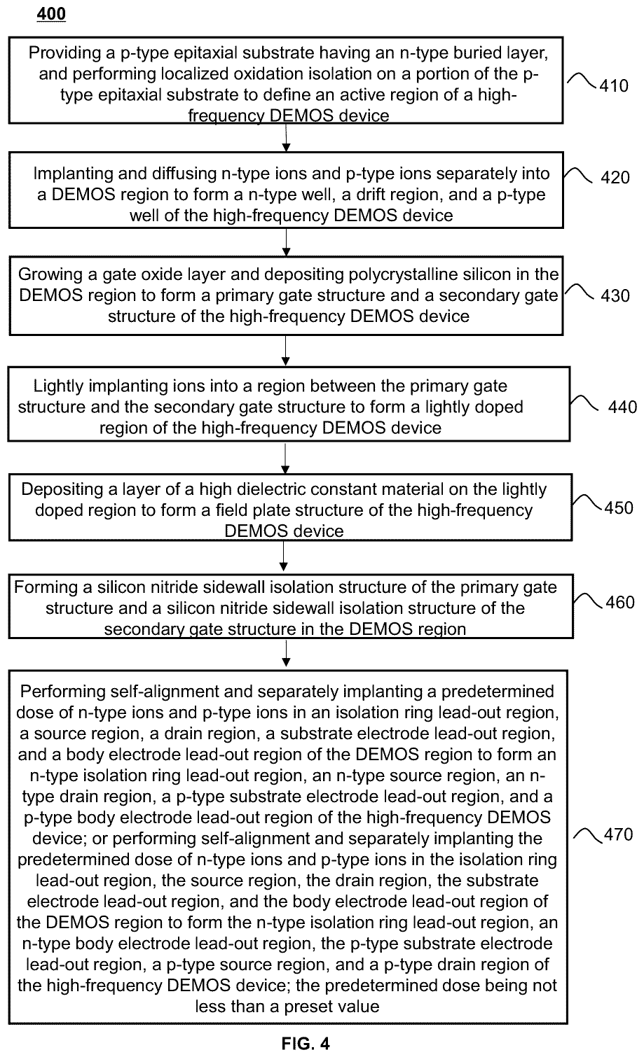

FIG. 4 is a flowchart of another exemplary process of a method for producing a high-frequency DEMOS device according to some embodiments of the present disclosure. Process 400 may produce the high-frequency DEMOS device described in FIG. 2, and process 400 includes operations 410-470.

In some embodiments, the method for producing the high-frequency DEMOS device includes: providing a p-type epitaxial substrate having an n-type buried layer, and performing localized oxidation isolation on a portion of the p-type epitaxial substrate to define an active region of the high-frequency DEMOS device; implanting and diffusing n-type ions and p-type ions separately into a DEMOS region to form the n-type well, the drift region, and the p-type well of the high-frequency DEMOS device; growing a gate oxide layer and depositing polycrystalline silicon in the DEMOS region to form the primary gate structure and the secondary gate structure of the high-frequency DEMOS device; lightly implanting ions into the region between the primary gate structure and the secondary gate structure to form the lightly doped region of the high-frequency DEMOS device; depositing a layer of a high dielectric constant material on the lightly doped region to form the field plate structure of the high-frequency DEMOS device; forming a silicon nitride sidewall isolation structure of the primary gate structure and a silicon nitride sidewall isolation structure of the secondary gate structure in the DEMOS region; and performing self-alignment and separately implanting a predetermined dose of n-type ions and p-type ions in an isolation ring lead-out region, the source region, the drain region, a substrate electrode lead-out region, and a body electrode lead-out region of the DEMOS region to form an n-type isolation ring lead-out region, an n-type source region, an n-type drain region, a p-type substrate electrode lead-out region, and a p-type body electrode lead-out region of the high-frequency DEMOS device; or performing self-alignment and separately implanting the predetermined dose of n-type ions and p-type ions in the isolation ring lead-out region, the source region, the drain region, the substrate electrode lead-out region, and the body electrode lead-out region of the DEMOS region to form the n-type isolation ring lead-out region, an n-type body electrode lead-out region, the p-type substrate electrode lead-out region, a p-type source region, and a p-type drain region of the high-frequency DEMOS device; the predetermined dose being not less than a preset value.

In 410, a p-type epitaxial substrate having an n-type buried layer is provided, and localized oxidation isolation is performed on a portion of the p-type epitaxial substrate to define an active region of the high-frequency DEMOS device.

The p-type epitaxial substrate refers to a substrate of a p-type semiconductor material having an epitaxial layer.

The localized oxidative isolation refers to a technique of forming one or more isolation regions on the p-type epitaxial substrate by a process of selective oxidation. The one or more isolation regions may include regions where shallow trench isolation oxides form on the surface of the silicon substrate described in FIG. 2. The shallow trench isolation oxides may include the first isolation oxide 207a, the second isolation oxide 207b, the third isolation oxide 207c, the fourth isolation oxide 207d, and the fifth isolation oxide 207e shown in FIG. 2.

The active region is a region on the p-type epitaxial substrate where an active device is fabricated.

In some embodiments, the active region of the p-type epitaxial substrate may be isolated by the isolation one or more regions.

In 420, n-type ions and p-type ions are separately implanted and diffused into a DEMOS region to form the n-type well, the drift region, and the p-type well of the high-frequency DEMOS device.

In some embodiments, n-type ions and p-type ions may be implanted and diffused in the DEMOS region by an ion implantation device to form the n-type well, the drift region, and the p-type well of the high-frequency DEMOS device. More descriptions of the ion implantation device may be found in the related descriptions below.

In 430, a gate oxide layer is grown and polycrystalline silicon is deposited in the DEMOS region to form the primary gate structure and the secondary gate structure of the high-frequency DEMOS device.

The DEMOS region may be a region on the p-type epitaxial substrate.

The gate oxide layer is a thin layer formed on a top of the p-type epitaxial substrate that isolates and protects other regions.

The primary gate structure may be configured to receive an input signal. The secondary gate structure may be configured to receive a fixed bias voltage. For more descriptions on the primary gate structure and the secondary gate structure, please refer to the related descriptions of FIG. 2.

In 440, ions are lightly implanted into a region between the primary gate structure and the secondary gate structure to form the lightly doped region of the high-frequency DEMOS device.

Lightly implanting is a process in which ions are implanted into a surface region of the p-type well between the primary gate structure and the secondary gate structure to form the lightly doped region.

In some embodiments, a region where ions are lightly implanted into the surface region of the p-type well located between the primary gate structure and the secondary gate structure may be determined as the lightly doped region.

In 450, a layer of a high dielectric constant material is deposited on the lightly doped region to form the field plate structure of the high-frequency DEMOS device.

More descriptions of the high dielectric constant material and the field plate structure may be found in the related descriptions of FIG. 2.

In 460, a silicon nitride sidewall isolation structure of the primary gate structure and a silicon nitride sidewall isolation structure of the secondary gate structure are formed in the DEMOS region.

The silicon nitride sidewall isolation structure is an isolation structure formed on sides of the primary gate structure and the secondary gate structure. In some embodiments, the isolation structure may be formed on the sides of the primary gate structure and the secondary gate structure by a processing technique such as etching.

In 470, self-alignment is performed and a predetermined dose of n-type ions and p-type ions are separately injected in an isolation ring lead-out region, the source region, the drain region, a substrate electrode lead-out region, and a body electrode lead-out region of the DEMOS region to form an n-type isolation ring lead-out region, an n-type source region, an n-type drain region, a p-type substrate electrode lead-out region, and a p-type body electrode lead-out region of the high-frequency DEMOS device; or self-alignment is performed and the predetermined dose of n-type ions and p-type ions are separately injected in the isolation ring lead-out region, the source region, the drain region, the substrate electrode lead-out region, and the body electrode lead-out region of the DEMOS region to form the n-type isolation ring lead-out region, an n-type body electrode lead-out region, the p-type substrate electrode lead-out region, a p-type source region, and a p-type drain region of the high-frequency DEMOS device; the predetermined dose being not less than a preset value. The predetermined dose is not less than a preset value. The preset value may be preset empirically. For example, the preset value may be no less than 10¹⁵ cm⁻².

More descriptions of the isolation ring lead-out region, the source region, the drain region, the substrate electrode lead-out region, and the body electrode lead-out region may be found in the related descriptions of FIG. 2.

The present disclosure improves the long gate structure of the conventional DEMOS device into the relatively short primary gate structure and the relatively long secondary gate structure. The gate length of the relatively short primary gate structure may be configured to be a minimum allowable gate length under a current process node, and the primary gate structure may be configured to receive an input signal. The gate length of the relatively long secondary gate structure may be determined based on an actual operating voltage, and the secondary gate structure may be configured to receive a fixed bias voltage. Merely by way of example, if the current process node is a 0.18 μm process node, then the minimum length of the primary gate structure is 0.18 μm.

Since the gate length of the primary gate structure of the high-frequency DEMOS device described herein is much smaller than the gate length of the gate structure of the conventional DEMOS device, a gate-to-drain capacitance (C_{gd}) of the high-frequency DEMOS device is significantly reduced, resulting in a substantial increase in a maximum cutoff frequency (fₜ), which leads to a marked improvement in high-frequency performance of the high-frequency DEMOS device. In addition, since the gate length of the secondary gate structure is relatively long and the secondary gate structure is configured to receive the fixed bias voltage, impact on a breakdown voltage (V_{BD}) of the high-frequency DEMOS device is minimum.

In the present disclosure, n-type ions (or p-type ions if the high-frequency DEMOS device is a p-type device) are lightly implanted into the region between the primary gate structure and the secondary gate structure to form the lightly doped region. A layer of the high-k material is then deposited on the lightly doped region. Because the lightly doped region is close to a boundary between the p-type well and the n-type drift region, electric field lines are dense and the electric field varies significantly, which greatly affects the breakdown voltage (V_{BD}) of the high-frequency DEMOS device. By lightly doping ions between the primary gate structure and the secondary gate structure and depositing the high-k material, an electric field distribution in the lightly doped region is effectively adjusted, thereby improving the breakdown voltage (V_{BD}) of the high-frequency DEMOS device.

In some embodiments, the method for producing the high-frequency DEMOS device further includes controlling an initial implantation dose of an ion implantation device to modulate an initial junction depth of the lightly doped region.

The ion implantation device is a device configured to implant ions into an interior of a p-type well (e.g., the p-type well 205b in FIG. 2).

The implantation dose refers to an amount of ions implanted into the p-type well by the ion implantation device. The implantation dose is one of parameters of the ion implantation device. It may be understood that the implantation dose may affect a doping level of the lightly doped region.

The initial implantation dose refers to an amount of ions injected by the ion implantation device in an initial state.

In some embodiments, the initial implantation dose may be determined based on a historical breakdown voltage.

The historical breakdown voltage refers to a voltage determined during historical testing or experimentation that causes the high-frequency DEMOS device to break down.

In some embodiments, the processor may retrieve the historical breakdown voltage from a storage device. The storage device stores historical processing data of the high-frequency DEMOS device. The historical processing data includes historical breakdown voltages collected from actual tests or experiments. The processor may be located at any position on a production line of the high-frequency DEMOS device or on a cloud platform. The cloud platform may include a community cloud, a private cloud, or the like.

In some embodiments, the processor may determine the initial implantation dose through operations S10-S14 as follows:

In S10, the historical processing data may be retrieved.

In some embodiments, the historical processing data includes historical junction depths and the historical breakdown voltages corresponding to a plurality of historical implantation doses obtained from actual tests or experiments. Different historical implantation doses may yield different production costs for the high-frequency DEMOS device.

A junction depth refers to a distance from a surface of the lightly doped region to a PN junction within the high-frequency DEMOS device.

The historical junction depths refer to the junction depths of historically produced high-frequency DEMOS devices.

In some embodiments, the processor may retrieve the historical processing data from the storage device.

In S11, historical processing data in which the historical breakdown voltage is greater than or equal to a minimum breakdown voltage may be filtered out from the historical processing data and determined as first historical processing data.

The first historical processing data refers to the historical processing data in which the historical breakdown voltage is greater than or equal to the minimum breakdown voltage.

The value of the minimum breakdown voltage may be preset according to actual needs.

In S12, target processing data may be determined based on the first historical processing data.

In some embodiments, the processor may determine first historical processing data that satisfies a preset condition as the target processing data. The preset condition may be set based on experience. For example, the preset condition may include the historical breakdown voltage being greater than the minimum breakdown voltage, and the historical breakdown voltage not exceeding the minimum breakdown voltage by a first preset factor (e.g., 1.1 times).

In S13, the initial implantation dose may be determined based on the target processing data.

In some embodiments, the processor may determine an average value of historical implantation doses corresponding to a plurality of pieces of target processing data, and designate the average value as the initial implantation dose.

The initial junction depth refers to a junction depth formed in the lightly doped region after the ion implantation device operates according to the initial implantation dose. A junction depth refers to a distance from the surface of the lightly doped region to the PN junction within the high-frequency DEMOS device.

In some embodiments, the processor may set a parameter of the ion implantation device to the initial implantation dose before the ion implantation device operates, thereby controlling the initial junction depth of the lightly doped region.

In some embodiments of the present disclosure, by controlling the initial implantation dose of the ion implantation device to regulate the initial junction depth of the lightly doped region, the stability of the processing quality of high-frequency DEMOS devices can be ensured.

In some embodiments, the method for producing the high-frequency DEMOS device also includes depositing, by a thin film deposition device, a high-k (high dielectric constant) material on the lightly doped region to obtain the high-k material with an initial deposition thickness.

The thin film deposition device refers to a device for depositing the high dielectric constant material on the surface of the lightly doped region. For example, the thin film deposition device may include an atomic layer deposition device, or the like.

The deposition thickness refers to a thickness of the high dielectric constant material deposited on the surface of the lightly doped region by the thin film deposition device. The initial deposition thickness refers to a deposition thickness in the initial state.

The initial deposition thickness may be predetermined by a person skilled in the art according to practical needs.

In some embodiments, control of the initial deposition thickness may be accomplished by controlling an initial deposition time of the thin film deposition device.

The deposition time refers to a duration for the thin film deposition device to deposit the high dielectric constant material on the surface of the lightly doped region. The initial deposition time refers to the deposition time in the initial state.

In some embodiments, the processor may determine a plurality of reference deposition times based on the initial deposition thickness and a deposition material type via a first preset reference table, and determine the initial deposition time based on the plurality of reference deposition times. The deposition material type may include material types such as hafnium dioxide, zirconium dioxide, titanium dioxide, or the like.

The first preset reference table includes a corresponding relationship between a same reference deposition thickness and a same reference deposition material type of a same type of high-frequency DEMOS devices and a plurality of reference deposition times, statistically obtained from historical processing data of all qualified high-frequency DEMOS devices. The first preset reference table may be constructed based on the historical processing data. In the historical processing data, a same deposition thickness may correspond to a plurality of deposition times. In some embodiments, the processor may construct the first preset reference table by correlating different reference deposition thicknesses and different reference deposition materials from the historical processing data with a plurality of actually measured deposition times corresponding to each of the different reference deposition thicknesses and the different reference deposition materials.

In some embodiments, the processor may determine a count of occurrences of each reference deposition time value based on the plurality of reference deposition times corresponding to the initial deposition thickness of the same type of high-frequency DEMOS devices, and determine a total count of occurrences of all reference deposition time values. For each reference deposition time value, the processor may determine a ratio of the count of occurrences of the reference deposition time value to the total count of occurrences of all reference deposition time values as a coefficient for the reference deposition time value. The processor may perform a weighted summation of the product of a plurality of reference deposition time values and the corresponding coefficients thereof, and determine a result of the weighted summation as the initial deposition time.

In some embodiments, the processor may obtain the high dielectric constant material with the initial deposition thickness by controlling the thin film deposition device to deposit the high dielectric constant material for the initial deposition time on the lightly doped region.

In some embodiments of the present disclosure, based on the determined initial deposition thickness, an optimal initial deposition time corresponding to the initial deposition thickness is determined through the historical processing data. The operating parameter of the thin-film deposition device is then set to the optimal initial deposition time to operate, forming the high-k material with the initial deposition thickness on the surface of the lightly doped region. This ensures that the production time cost and high-k material cost for the high-frequency DEMOS device are effectively controlled under the prerequisite that the deposition thickness meets usage requirements of the high-frequency DEMOS device.

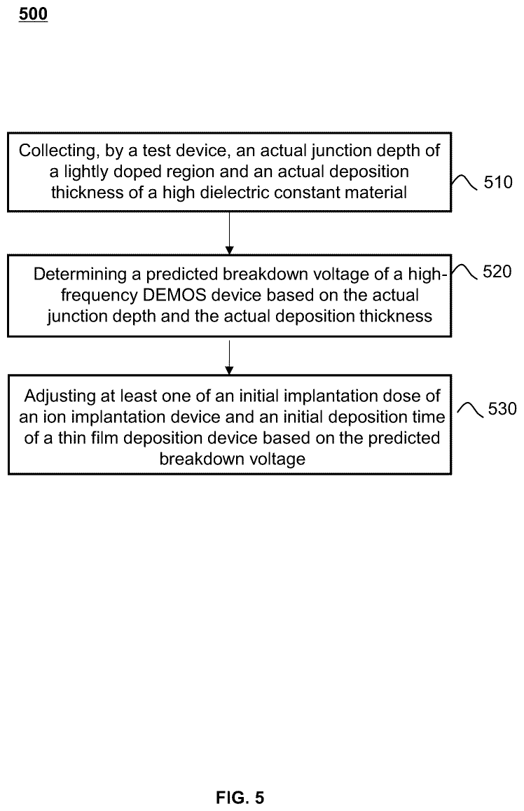

In some embodiments, after the processor controls the thin-film deposition device to deposit for the initial deposition time on the surface of the lightly doped region and controls the ion implantation device to operate with the initial implantation dose, the method for producing the high-frequency DEMOS device further includes collecting, by a test device, an actual junction depth of the lightly doped region, and an actual deposition thickness of the high dielectric constant material; determining a predicted breakdown voltage of the high-frequency DEMOS device based on the actual junction depth and the actual deposition thickness; and adjusting at least one of the initial implantation dose of the ion implantation device and the initial deposition time of the thin film deposition device based on the predicted breakdown voltage. For more descriptions of this section, see the related descriptions of FIG. 5.

FIG. 5 is a flowchart of an example process for adjusting at least one of an initial implantation dose of an ion implantation device and an initial deposition time of a thin film deposition device according to some embodiments of the present disclosure. Process 500 may be executed by a processor. The processor may be located anywhere in a production line of a high-frequency DEMOS device or in a cloud platform. The cloud platform may include a community cloud, a private cloud, or the like. Process 500 may include operations 510-530.

In 510, an actual junction depth of a lightly doped region and an actual deposition thickness of a high dielectric constant material may be collected by a test device.

In some embodiments, the test device refers to a device that collects the actual junction depth of the lightly doped region and the actual deposition thickness of the high dielectric constant material deposited on a surface of the lightly doped region. The test device may include a scanning electron microscope, a transmission electron microscope, or the like.

The actual junction depth is a junction depth obtained by actual measurement. The actual deposition thickness is an actually measured deposition thickness of the high dielectric constant material. More descriptions of the junction depth and the deposition thickness may be found in the relevant descriptions of FIG. 4. More descriptions of the lightly doped regions and the high dielectric constant material may be found in the relevant descriptions of FIG. 1.

In 520, a predicted breakdown voltage of the high-frequency DEMOS device may be determined based on the actual junction depth and the actual deposition thickness.

The predicted breakdown voltage is a predicted voltage at which the high-frequency DEMOS device is expected to break down.

In some embodiments, the processor may determine the predicted breakdown voltage of the high-frequency DEMOS device based on the actual junction depth and the actual deposition thickness via a second preset reference table. The second preset reference table includes a correspondence between reference junction depths, reference deposition thicknesses, and predicted breakdown voltages of reference high-frequency DEMOS devices. The second preset reference table may be constructed based on prior knowledge or historical data.

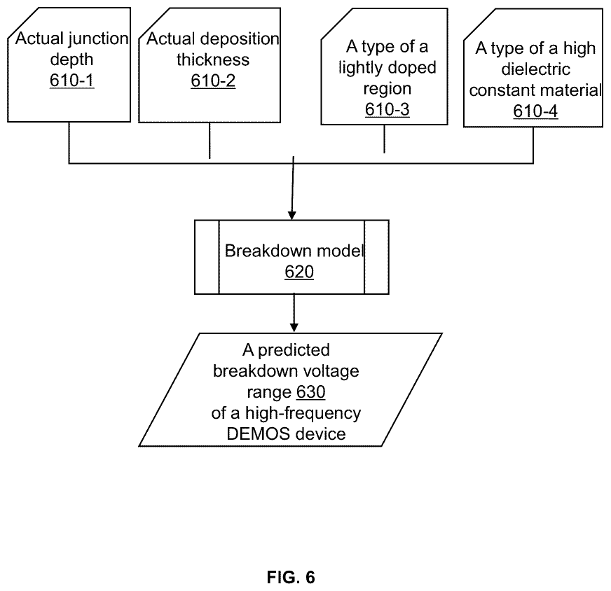

In some embodiments, the processor may determine, via a breakdown model, a predicted breakdown voltage range of the DEMOS device based on the actual junction depth, the actual deposition thickness, a type of the lightly doped region, and a type of the high dielectric constant material, and determine, based on the predicted breakdown voltage range, the predicted breakdown voltage. More descriptions of the breakdown model may be found in the related descriptions of FIG. 6.

In some embodiments, the processor may designate a lower limit value of the predicted breakdown voltage range as the predicted breakdown voltage. The lower limit value is a smallest predicted breakdown voltage in the predicted breakdown voltage range. Determining the predicted breakdown voltage of a high-frequency DEMOS device based on the actual junction depth and the actual deposition thickness obtained from a single measurement does not exclude the influence of accidental factors, which results in the inaccuracy of the predicted breakdown voltage of the high-frequency DEMOS device. Therefore, a plurality of actual junction depths and a plurality of actual deposition thicknesses may be obtained from multiple measurements performed by the test device to determine the predicted breakdown voltage of the high-frequency DEMOS device, in order to improve the accuracy of the predicted breakdown voltage of the high-frequency DEMOS device.

In some embodiments, the processor may determine the predicted breakdown voltage of the high-frequency DEMOS device through operations K1-K3:

In K1, a target junction depth may be determined based on a plurality of actual junction depths.

In some embodiments, the plurality of actual junction depths and the plurality of actual deposition thicknesses may be obtained by measuring a plurality of high-frequency DEMOS devices of a same type using a same test device. The plurality of high-frequency DEMOS devices of the same type are high-frequency DEMOS devices obtained by processing the DEMOS region using a same initial deposition time and a same initial implantation dose.

Understandably, there may be slight deviations between the actual junction depths and the actual deposition thicknesses of a plurality of qualified high-frequency DEMOS devices of the same type (e.g., the plurality of qualified high-frequency DEMOS devices may correspond to a plurality of deposition thicknesses), but all meet production requirements. The slight deviations may be at the nanometer scale.

In some embodiments, the plurality of actual junction depths and the plurality of actual deposition thicknesses may also be obtained by making multiple measurements of a same high-frequency DEMOS device using different test devices.

In some embodiments, the processor may obtain the plurality of actual junction depths and the plurality of actual deposition thicknesses by the test device.

The target junction depth refers to the finally determined junction depth. More descriptions of the junction depth may be found in the related descriptions of FIG. 4.

In some embodiments, the processor determines the target junction depth based on the plurality of actual junction depths in a manner similar to the manner of determining the initial deposition time as described above.

In K2, a target deposition thickness may be determined based on the plurality of actual deposition thicknesses.

The target deposition thickness refers to the finally determined deposition thickness. More descriptions of the deposition thickness may be found in the related descriptions of FIG. 4.

In some embodiments, the processor determines the target deposition thickness based on the plurality of actual deposition thicknesses in a manner similar to the manner of determining the initial deposition time as described above.

In K3, the predicted breakdown voltage may be determined based on the target junction depth and the target deposition thickness.

In some embodiments, the processor may determine, based on the target junction depth, the target deposition thickness, the type of the lightly doped region, and the type of high dielectric constant material, the predicted breakdown voltage range of the high-frequency DEMOS device via the breakdown model, and determine the predicted breakdown voltage based on the predicted breakdown voltage range. More descriptions of the breakdown model may be found in the related descriptions of FIG. 6. In some embodiments, the processor may take the lower limit value of the predicted breakdown voltage range as the predicted breakdown voltage.

In some embodiments of the present disclosure, by determining the predicted breakdown voltage of the high-frequency DEMOS device based on the target junction depth and the target deposition thickness that are determined by the plurality of actual junction depths and the plurality of actual deposition thicknesses, respectively, the accuracy of the determined predicted breakdown voltage can be further improved.

In 530, at least one of the initial implantation dose of the ion implantation device and the initial deposition time of the thin film deposition device may be adjusted based on the predicted breakdown voltage.

In some embodiments, the processor may compare the lower limit value of the predicted breakdown voltage range of the high-frequency DEMOS device with a minimum breakdown voltage. In response to the lower limit value of the predicted breakdown voltage range of the high-frequency DEMOS device being greater than or equal to the minimum breakdown voltage, at least one of the initial implantation dose of the ion implantation device and the initial deposition time of the thin film deposition device is not adjusted. In response to the lower limit value of the predicted breakdown voltage range of the high-frequency DEMOS device being less than the minimum breakdown voltage, at least one of the initial implantation dose of the ion implantation device and the initial deposition time of the thin film deposition device is adjusted.

In some embodiments, the processor may adjust the preset condition in operation S12 of FIG. 4, and then perform the operation S10-S13 of FIG. 4 to determine an adjusted initial implantation dose of the ion implantation device, and adjust the initial implantation dose of the ion implantation device based on the adjusted initial implantation dose. The adjusted preset condition may include the historical breakdown voltage being greater than the minimum breakdown voltage, and the historical breakdown voltage not exceeding the minimum breakdown voltage by a second preset factor.

In some embodiments, the processor may first designate a randomly increased or decreased first preset factor as the second preset factor. If the lower limit value of the predicted breakdown voltage range of the high-frequency DEMOS device output by the breakdown model is smaller than the minimum breakdown voltage, the processor continues to increase or decrease the second preset factor based on the previous second preset factor. If the lower limit value of the predicted breakdown voltage range of the high-frequency DEMOS device output by the breakdown model is smaller than the lower limit value of the predicted breakdown voltage range of the high-frequency DEMOS device from the previous breakdown model output, the second preset factor is reset to the first preset factor, and the adjustment direction of the first preset factor is reversed (for example, changing from increasing the first preset factor to decreasing it), and the adjusted first preset factor is determined as the second preset factor.

For example, the processor may first randomly increase the first preset factor by 1.2 times and use 1.2 times of the first preset factor as the second preset factor. If the lower limit value (e.g., 60V) of the predicted breakdown voltage range range of the high-frequency DEMOS device output by the breakdown model is lower than the minimum breakdown voltage (e.g., 100V), the processor may further increase the first preset factor by 1.3 times based on the previous second preset factor and use 1.3 times of the first preset factor as the new second preset factor. If the lower limit value (e.g., 58V) of the predicted breakdown voltage range range is lower than the previous lower limit value (e.g., 60V), the second preset factor is reset to the first preset factor, and the adjustment direction of the first preset factor is switched from increasing to decreasing, using the reduced first preset factor as the second preset factor.

In some embodiments, an extent of increase in the first preset factor may be positively or negatively correlated with a ratio of a specific difference to the minimum breakdown voltage. The specific difference refers to a difference between the lower limit value of the predicted breakdown voltage range and the minimum breakdown voltage.

In some embodiments, the processor may determine, based on the historical adjustment results, whether the extent of increase in the first preset factor is positively or negatively correlated with the ratio of the specific difference to the minimum breakdown voltage. The historical adjustment results reflect whether, under different historical conditions, the extent of increase in the first preset factor is positively or negatively correlated with the ratio of the specific difference to the minimum breakdown voltage, such that the lower limit value of the predicted breakdown voltage range of the high-frequency DEMOS device output by the breakdown model greater than or equal to the minimum breakdown voltage. The historical adjustment results are stored in a storage device.

For example, if the historical adjustment results show that in similar historical conditions, the extent of increase in the first preset factor being positively correlated with the ratio of the specific difference to the minimum breakdown voltage makes the lower limit value of the predicted breakdown voltage range of the high-frequency DEMOS device output by the breakdown model to be greater than or equal to the minimum breakdown voltage, then the extent of increase in the first preset factor is set to be positively correlated with the ratio of the specific difference to the minimum breakdown voltage.

Specifically, the processor may first increase the first preset factor by a first preset increment (e.g., increasing to 1.1 times of the first preset factor) and designate the increased first preset factor as the second preset factor. Then, following the operations S10-S13 of FIG. 4, the processor determines the adjusted initial implantation dose for the ion implantation device to control the initial junction depth of the lightly doped region. Based on the adjusted initial junction depth, the initial deposition time, the type of the lightly doped region, and the type of the high dielectric constant material, the predicted breakdown voltage range of the high-frequency DEMOS device is re-determined via the breakdown model. If, after increasing the first preset factor, the lower limit value of the predicted breakdown voltage range output by the breakdown model is still smaller than the minimum breakdown voltage, the processor resets the second preset factor to the first preset factor and then decreases the first preset factor by the preset increment. This process continues until the lower limit value of the predicted breakdown voltage range output by the breakdown model is greater than or equal to the minimum breakdown voltage. More descriptions of the breakdown model may be found in the related descriptions of FIG. 6.

In some embodiments, the processor may determine, based on an initial deposition thickness and a deposition material type, a plurality of reference deposition times by querying a first preset reference table, and determine, based on the plurality of reference deposition times, an adjusted initial deposition time of the thin film deposition device.

More descriptions of determining the plurality of reference deposition times may be found in FIG. 4 and the related descriptions thereof.

In some embodiments, the processor may determine a count of occurrences of each reference deposition time value based on the plurality of reference deposition times corresponding to the initial deposition thickness of the same type of high-frequency DEMOS devices, and determine a total count of occurrences of all reference deposition time values. For each reference deposition time value, the processor may determine a ratio of the count of occurrences of the reference deposition time value to the total count of occurrences of all reference deposition time values as a coefficient for the reference deposition time value. The processor may perform a weighted summation of the product of a plurality of reference deposition time values and the corresponding coefficients thereof, and determine a result of the weighted summation as the initial deposition time. The processor may multiply the initial deposition time by a time coefficient to determine the adjusted initial deposition time of the thin film deposition device.

In some embodiments, the time coefficient is positively or negatively correlated with an absolute value of a difference between the initial deposition time and an average deposition time. In some embodiments, the manner of determining the absolute value of the difference between the initial deposition time and the average deposition time is similar to the manner of determining whether the increase in the first preset factor is positively or negatively correlated to the ratio of the specific difference to the minimum breakdown voltage. More descriptions may be found in the related descriptions above.

The average deposition time refers to an average of a plurality of reference deposition times corresponding to the same initial deposition thickness. The plurality of reference deposition times corresponding to the same initial deposition thickness may be determined by querying the first preset reference table.

In some embodiments, the processor may obtain the high dielectric constant material with the adjusted initial deposition thickness by controlling the thin film deposition device to deposit the high dielectric constant material on the lightly doped region for the adjusted initial deposition time.

In some embodiments, the processor may re-determine, through the breakdown model, the predicted breakdown voltage range of the high-frequency DEMOS device based on the adjusted initial junction depth, the adjusted initial deposition thickness, the type of the lightly doped region, and the type of the high dielectric constant material. More descriptions of the breakdown model may be found in the related descriptions of FIG. 6.

In some embodiments, the processor may compare the lower limit value of the predicted breakdown voltage range of the high-frequency DEMOS device with the minimum breakdown voltage. If the lower limit value of the predicted breakdown voltage range is smaller than the minimum breakdown voltage, the processor may re-adjust at least one of the initial ion implantation dose and the initial deposition time of the thin film deposition device according to the previously described method, until the lower limit value of the predicted breakdown voltage range is greater than or equal to the minimum breakdown voltage.

In some embodiments of the present disclosure, by generating the predicted breakdown voltage in advance, a forecast of the processing quality for high-frequency DEMOS devices can be made. When the forecast does not meet requirements, subsequent processing parameters can be adjusted in a timely manner to meet precision processing needs, ensure processing quality, and reduce production costs. The processing parameters may include the initial deposition time of the thin film deposition device, the initial ion implantation dose of the ion implantation device, or the like.

FIG. 6 is a flowchart of an exemplary process for determining a predicted breakdown voltage range of a high-frequency DEMOS device according to some embodiments of the present disclosure.

In some embodiments, a processor determines, through a breakdown model 620, a predicted breakdown voltage range 630 of the high-frequency DEMOS device based on an actual junction depth 610-1, an actual deposition thickness 610-2, a type of a lightly doped region 610-3, and a type of a high dielectric constant material 610-4.

The type of the lightly doped region 610-3 may include a p-type well or an n-type well. The type of the high dielectric constant material 610-4 may include material types such as hafnium dioxide, zirconium dioxide, titanium dioxide, or the like.

More descriptions of the actual junction depth and the actual deposition thickness may be found in FIG. 4 and the related descriptions thereof.

In some embodiments, the breakdown model 620 is a machine learning model. For example, the breakdown model 620 may include a neural network (NN) model, a deep neural network (DNN) model, or the like.

In some embodiments, if the predicted breakdown voltage range corresponds to a single predicted breakdown voltage, an upper limit value and a lower limit value of the predicted breakdown voltage range are the same.

In some embodiments, the processor may train an initial breakdown model to obtain the breakdown model via a training data set. The training data set includes a plurality of sub-training datasets. A sub-training dataset includes a plurality of training samples and labels corresponding to the plurality of training samples, respectively.

In some embodiments, a training sample includes a historical sample junction depth, a historical sample deposition thickness, a type of a historical sample lightly doped region, and a type of a historical sample high dielectric constant material corresponding to a historical sample DEMOS device. The label of the training sample is a historical sample breakdown voltage range corresponding to the training sample.

In some embodiments, the processor may determine a plurality of training samples based on historical processing data. The historical processing data includes actual junction depths, actual deposition thicknesses, types of lightly doped regions, and types of high dielectric constant materials corresponding to historical DEMOS devices. For a more detailed description of the historical processing data, please refer to the related description of FIG. 4.

In some embodiments, the processor may determine the label based on at least one historical breakdown voltage range corresponding to the historical processing data.

For example, the processor may determine a count of occurrences of historical breakdown voltages of different values corresponding to a same historical high-frequency DEMOS device based on the historical processing data. Then the processor may determine a maximum historical breakdown voltage and a minimum historical breakdown voltage, which occur more than a preset count threshold (e.g., 3 times), as the upper limit value and the lower limit value of the predicted breakdown voltage range, respectively, to obtain the training label.

In some embodiments, the processor may input a plurality of labeled training samples into the initial breakdown model, perform multiple rounds of iterations until an iteration end condition is satisfied, and obtain a trained breakdown model.

Each of the multiple rounds of iterations includes the following operations S20-S23:

In S20, a training sample and the label corresponding to the training sample are selected from the training dataset.

In S21, the training sample may be input into the initial breakdown model to obtain an output of the initial breakdown model corresponding to the current round of training of the training sample.

In S22, the output of the initial breakdown model corresponding to the current round of training of the training sample and the label of the training sample may be substituted into a predefined loss function formula, and a value of the loss function is determined.

In S23, a model parameter of the initial breakdown model may be inversely updated based on the value of the loss function. The initial breakdown model may be inversely updated using various techniques, for example, a gradient descent technique.

In some embodiments, the iteration end condition may include the loss function converging, a count of iterations reaching a threshold, or the like.

In some embodiments, the training process of the breakdown model further includes operations S30-S31:

In S30, the plurality of sub-training datasets may be obtained based on different historical breakdown voltages corresponding to the same type of historical high-frequency DEMOS devices in the historical processing data, wherein the labels of the plurality of training samples of a sub-training dataset are the same.

In some embodiments, the count of occurrences of different historical breakdown voltages corresponding to the same type of historical high-frequency DEMOS devices may be different when multiple experiments are performed on the same type of historical high-frequency DEMOS devices.

In some embodiments, the processor classifies a plurality of training samples, corresponding to historical breakdown voltages of the same type of historical high-frequency DEMOS device that satisfy a specific condition, into a sub-training dataset. The specific condition may be preset empirically by a person skilled in the art. For example, the specific condition may include that the plurality of training samples have a same historical breakdown voltage.

In S31, a learning rate of the initial breakdown model corresponding to the training dataset may be adjusted based on a stability degree of output results of each of a plurality of sub-training datasets of the training dataset.

The stability degree reflects a degree of fluctuation in the output results of the sub-training dataset. In some embodiments, the stability degree is expressed as a numerical value. For example, the smaller the value is, the higher the stability degree is.

In some embodiments, the processor may take an average value of variances of the output results and the label in a same sub-training dataset as the stability degree of the output results of the sub-training dataset.

In some embodiments, the processor may also determine an average value of the stability degrees of the output results of the plurality of sub-training datasets of the training dataset as a stability degree of output results of the training dataset.

In some embodiments, the processor adjusts the learning rate of the initial breakdown model corresponding to the training dataset based on the stability degree of the output results of the training dataset. For example, the lower the stability degree of the output results of the training dataset is, the lower the learning rate of the initial breakdown model corresponding to the training dataset is.

In some embodiments of the present disclosure, by adjusting the learning rate of the initial breakdown model corresponding to the training dataset based on the stability degrees of the output results of different sub-training datasets, the accuracy of the final predicted results of the breakdown model obtained through training can be improved.

Some embodiments of the present disclosure provide a high-frequency DEMOS device. The high-frequency DEMOS device includes a silicon substrate, a well region, a source region, a drain region, a drift region, a lightly doped region, and a gate structure. The gate structure includes a primary gate structure and a secondary gate

structure. The primary gate structure is disposed on a p-type well or an n-type well of the well region, and the primary gate structure is configured to receive an input signl. The secondary gate structure covers part of the p-type well and part of the drift region, or the secondary gate structure covers part of the n-type well and part of the drift region. The secondary gate structure is configured to receive a fixed bias voltage.

A gate length of the primary gate structure is smaller than a gate length of a conventional DEMOS device.

The lightly doped region is disposed on a surface of the p-type well or a surface of the n-type well, and the lightly doped region is located between the primary gate structure and the secondary gate structure.

The high-frequency DEMOS device further includes a field plate structure covering the lightly doped region.

The gate length of the primary gate structure is set to be a minimum allowable gate length of the primary gate structure under a current process node

A material of the field plate structure is a high dielectric constant material.

The primary gate structure includes a gate oxide layer, a gate polysilicon layer, and a silicon nitride sidewall.

The secondary gate structure includes a gate oxide layer, a gate polysilicon layer and a silicon nitride sidewall.

For a more detailed description of the high-frequency DEMOS device, see the related description of FIG. 2.

Having thus described the basic concepts, it may be rather apparent to those skilled in the art after reading this detailed disclosure that the foregoing detailed disclosure is intended to be presented as illustrative example and is not limiting. Various alterations, improvements, and modifications may occur and are intended to those skilled in the art, though not expressly stated herein. These alterations, improvements, and modifications are intended to be suggested by this disclosure, and are within the spirit and scope of the exemplary embodiments of the present disclosure.

Moreover, certain terminology has been configured to describe embodiments of the present disclosure. For example, the terms “one embodiment,” “an embodiment,” and/or “some embodiments” mean that a particular feature, structure, or characteristic described in connection with the embodiment is included in at least one embodiment of the present disclosure. Therefore, it is emphasized and should be appreciated that two or more references to “an embodiment” or “one embodiment” or “an alternative embodiment” in various portions of this disclosure are not necessarily all referring to the same embodiment. Furthermore, the particular features, structures, or characteristics may be combined as suitable in one or more embodiments of the present disclosure.

Furthermore, the recited order of processing elements or sequences, or the use of numbers, letters, or other designations therefore, is not intended to limit the claimed processes and methods to any order except as may be specified in the claims. Although the above disclosure discusses through various examples what is currently considered to be a variety of useful embodiments of the disclosure, it is to be understood that such detail is solely for that purpose, and that the appended claims are not limited to the disclosed embodiments, but, on the contrary, are intended to cover modifications and equivalent arrangements that are within the spirit and scope of the disclosed embodiments. For example, although the implementation of various components described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various inventive embodiments. This way of disclosure, however, is not to be interpreted as reflecting an intention that the claimed subject matter requires more features than are expressly recited in each claim. Rather, inventive embodiments lie in less than all features of a single foregoing disclosed embodiment.

In some embodiments, the numbers expressing quantities or properties configured to describe and claim certain embodiments of the present disclosure are to be understood as being modified in some instances by the term “about,” “approximate,” or “substantially.” For example, “about,” “approximate,” or “substantially” may indicate ±20% variation of the value it describes, unless otherwise stated. Accordingly, in some embodiments, the numerical parameter set forth in the written description and attached claims are approximations that may vary depending upon the desired properties sought to be obtained by a particular embodiment. In some embodiments, the numerical parameter should be construed in light of the number of reported significant digits and by applying ordinary rounding techniques. Notwithstanding that the numerical ranges and parameter setting forth the broad scope of some embodiments of the present disclosure are approximations, the numerical values set forth in the specific examples are reported as precisely as practicable.

Each of the patents, patent applications, publications of patent applications, and other material, such as articles, books, specifications, publications, documents, things, and/or the like, referenced herein is hereby incorporated herein by this reference in its entirety for all purposes, excepting any prosecution file history associated with same, any of same that is inconsistent with or in conflict with the present document, or any of same that may have a limiting effect as to the broadest scope of the claims now or later associated with the present document. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the present disclosure disclosed herein are illustrating of the principles of the embodiments of the present disclosure. Other modifications that may be employed may be within the scope of the present disclosure. Thus, by way of example, but not of limitation, alternative configurations of the embodiments of the present disclosure may be utilized in accordance with the teachings herein. Accordingly, embodiments of the present disclosure are not limited to that precisely as shown and described.

What is claimed is:

1. A high-frequency drain-extended metal-oxide-semiconductor (DEMOS) device, comprising a silicon substrate, a well region, a source region, a drain region, a drift region, a lightly doped region, a gate structure, and a field plate structure, wherein
the gate structure includes a primary gate structure and a secondary gate structure, the primary gate structure is disposed on a p-type well or an n-type well of the well region, and the primary gate structure is configured to receive an input signal; the secondary gate structure covers part of the p-type well and part of the drift region, or the secondary gate structure covers part of the n-type well and part of the drift region; the secondary gate structure is configured to receive a fixed bias voltage;
a gate length of the primary gate structure is smaller than a gate length of a gate structure of a conventional DEMOS device;
the lightly doped region is disposed on a surface of the p-type well or a surface of the n-type well, and the lightly doped region is located between the primary gate structure and the secondary gate structure; and
the field plate structure covers the lightly doped region.

2. The high-frequency DEMOS device of claim 1, wherein the gate length of the primary gate structure satisfies a predetermined gate length condition, the predetermined gate length condition being related to a minimum allowable gate length of the primary gate structure under a current process node.

3. The high-frequency DEMOS device of claim 1, wherein a material of the field plate structure is a high dielectric constant material.

4. The high-frequency DEMOS device of claim 1, wherein the primary gate structure includes a gate oxide layer, a gate polysilicon layer, and a silicon nitride sidewall.

5. The high-frequency DEMOS device of claim 1, wherein the secondary gate structure includes a gate oxide layer, a gate polysilicon layer, and a silicon nitride sidewall.

6. A method of producing a high-frequency DEMOS device, the high-frequency DEMOS device being the high-frequency DEMOS device of claim 1, and the method comprising:
providing a p-type epitaxial substrate having an n-type buried layer, and performing localized oxidation isolation on a portion of the p-type epitaxial substrate to define an active region of the high-frequency DEMOS device;
implanting and diffusing n-type ions and p-type ions separately into a DEMOS region to form the n-type well, the drift region, and the p-type well of the high-frequency DEMOS device;
growing a gate oxide layer and depositing polycrystalline silicon in the DEMOS region to form the primary gate structure and the secondary gate structure of the high-frequency DEMOS device;
lightly implanting ions into the region between the primary gate structure and the secondary gate structure to form the lightly doped region of the high-frequency DEMOS device;
depositing a layer of a high dielectric constant material on the lightly doped region to form the field plate structure of the high-frequency DEMOS device;
forming a silicon nitride sidewall isolation structure of the primary gate structure and a silicon nitride sidewall isolation structure of the secondary gate structure in the DEMOS region; and
performing self-alignment and separately implanting a predetermined dose of n-type ions and p-type ions in an isolation ring lead-out region, the source region, the drain region, a substrate electrode lead-out region, and a body electrode lead-out region of the DEMOS region to form an n-type isolation ring lead-out region, an n-type source region, an n-type drain region, a p-type substrate electrode lead-out region, and a p-type body electrode lead-out region of the high-frequency DEMOS device; or performing self-alignment and separately implanting the predetermined dose of n-type ions and p-type ions in the isolation ring lead-out region, the source region, the drain region, the substrate electrode lead-out region, and the body electrode lead-out region of the DEMOS region to form the n-type isolation ring lead-out region, an n-type body electrode lead-out region, the p-type substrate electrode lead-out region, a p-type source region, and a p-type drain region of the high-frequency DEMOS device; the predetermined dose being not less than a preset value.

7. The method of claim 6, further comprising:
controlling an initial implantation dose of an ion implantation device, and modulating an initial junction depth of the lightly doped region, wherein the initial implantation dose is determined based on a historical breakdown voltage.

8. The method of claim 7, further comprising:
collecting, by a test device, an actual junction depth of the lightly doped region and an actual deposition thickness of the high dielectric constant material;
determining a predicted breakdown voltage of the high-frequency DEMOS device based on the actual junction depth and the actual deposition thickness; and
adjusting the initial implantation dose of the ion implantation device based on the predicted breakdown voltage.

9. The method of claim 6, further comprising:
depositing, by a thin film deposition device, the high dielectric constant material on the lightly doped region to obtain the high dielectric constant material with an initial deposition thickness, control of the initial deposition thickness being achieved by controlling an initial deposition time of the thin film deposition device.

10. The method of claim 9, further comprising:
collecting, by a test device, an actual junction depth of the lightly doped region and an actual deposition thickness of the high dielectric constant material;
determining a predicted breakdown voltage of the high-frequency DEMOS device based on the actual junction depth and the actual deposition thickness; and
adjusting the initial deposition time of the thin film deposition device based on the predicted breakdown voltage.

11. The method of claim 10, wherein the determining a predicted breakdown voltage of the high-frequency DEMOS device based on the actual junction depth and the actual deposition thickness includes:
determining a predicted breakdown voltage range of the high-frequency DEMOS device via a breakdown model based on the actual junction depth, the actual deposition thickness, a type of the lightly doped region, and a type of the high dielectric constant material, wherein the breakdown model is a machine learning model, the breakdown model is obtained by training an initial breakdown model with a training dataset, the training dataset includes a plurality of sub-training datasets, a sub-training dataset of the plurality of sub-training datasets includes a plurality of training samples and labels corresponding to the plurality of training samples, respectively; and
a training process of the breakdown model includes:
obtaining the plurality of sub-training datasets based on different historical breakdown voltages corresponding to a same type of historical high-frequency DEMOS devices in historical processing data, wherein the labels corresponding to the plurality of training samples of the sub-training dataset are the same; and
adjusting a learning rate of the initial breakdown model corresponding to the training dataset based on a stability degree of output results of each of the plurality of sub-training datasets.

12. The method of claim 10, wherein the determining a predicted breakdown voltage of the high-frequency DEMOS device based on the actual junction depth and the actual deposition thickness includes:
determining a target junction depth based on a plurality of actual junction depths;
determining a target deposition thickness based on a plurality of actual deposition thicknesses; and
determining the predicted breakdown voltage based on the target junction depth and the target deposition thickness.
